(19) United States
(12) Patent Application Publication
(10) Pub. No.: US 2007/0054482 A1
(43) Pub. Date: Mar. 8, 2007

(54) Semiconductor device fabrication method

(76) Inventors: Takahito Nakajima, Yokkaichi-Shi (JP); Yoshihiro Uozumi, Yokohama-Shi (JP); Mikie Miyasato, Yamato-Shi (JP); Tsuyoshi Matsumura, Hiratsuka-Shi (JP); Yasuhito Yoshimizu, Yokohama-Shi (JP); Hiroshi Tomita, Yokohama-Shi (JP); Hiroki Sakurai, Yokohama-Shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/501,109

(22) Filed: Aug. 9, 2006

Related U.S. Application Data
(63) Continuation-in-part of application No. 11/199,241, filed on Aug. 9, 2005.

(30) Foreign Application Priority Data
Aug. 10, 2004 (JP) 2004-233405
Dec. 13, 2005 (JP) 2005-358703

(51) Int. Cl. H01L 21/44

(52) U.S. Cl. 438/597

(57) ABSTRACT

According to one aspect of the invention, there is provided a semiconductor device fabrication method having: forming a film on a semiconductor substrate; forming a mask comprising a predetermined pattern on the film; etching one of the film and the semiconductor substrate by using the mask; and performing at least one of the steps of performing a treatment using one of an aqueous solution of at least one of ammonia and amine, the amine being selected from primary amine, secondary amine, tertiary amine, and quaternary amine, a treatment using a liquid chemical containing fluorine and at least one of amine, the amine being selected from primary amine, secondary amine, tertiary amine, and quaternary amine and fluorine, and a treatment using a liquid chemical containing at least ammonia and fluorine and including a pH of not less than 6, particularly, not less than 9.

### CROSS REFERENCE TO RELATED APPLICATION

This application is based upon and claims benefit of priority under 35 USC §119 from the Japanese Patent Applications No. 2004-233405, filed on Aug. 10, 2004, and No. 2005-358703, filed on Dec. 13, 2005, the entire contents of which are incorporated herein by reference.

### BACKGROUND OF THE INVENTION

The present invention relates to a semiconductor device fabrication method.

In the semiconductor fabrication process, an interlayer dielectric film is formed on a semiconductor substrate having a semiconductor element such as a MISFET, and a contact plug which contacts the surface of the semiconductor substrate is formed in the interlayer dielectric film. Another interlayer dielectric film is then formed on the interlayer dielectric film and contact plug.

This interlayer dielectric film is coated with a photoresist, and the photoresist is exposed and developed to form a resist mask having a pattern which opens above the upper surface of the contact plug.

This resist mask is used as a mask to etch away the surface portion of the interlayer dielectric film by a predetermined depth, thereby forming an interconnecting trench in the interlayer dielectric film, and exposing the upper surface of the contact plug.

After the resist mask is oxidized away, the deposit such as the resist residue is removed by using a liquid chemical which contains an organic solvent as a major ingredient and NH₄F.

Unfortunately, even when the residue is to be etched away by using this organic F liquid chemical, the residue cannot be completely removed because the removable etching amount of the dielectric film is limited. This deteriorates the transistor characteristics.

Also, to completely remove the residue, etching must be strongly performed. In this case, etching progresses in the lateral direction of the interconnecting trench to increase its width. If copper is buried in this trench to form a copper interconnection which connects to the contact plug, the width of this copper interconnection becomes larger than the mask pattern. Since this makes the wiring resistance different from the design value, the characteristics vary.

A reference concerning the removal of the resist residue is as follows.

PCT(WO) 2002-520812

### SUMMARY OF THE INVENTION

According to one aspect of the present invention, there is provided a semiconductor device fabrication method comprising:

forming a film on a semiconductor substrate;

forming a mask comprising a predetermined pattern on the film;

etching one of the film and the semiconductor substrate by using the mask; and

performing at least one of the steps of performing a treatment using one of an aqueous solution of at least one of ammonia and amine, the amine being selected from primary amine, secondary amine, tertiary amine, and quaternary amine, a treatment using a liquid chemical containing fluorine and at least one of amine, the amine being selected from primary amine, secondary amine, tertiary amine, and quaternary amine, and a treatment using a liquid chemical containing at least ammonia and fluorine and including a pH of not less than 6, particularly, not less than 9.

According to one aspect of the present invention, there is provided a semiconductor device fabrication method comprising:

forming a conductive film by depositing a conductive material on a semiconductor substrate;

removing a desired region of the conductive film;

forming an interlayer dielectric film on the semiconductor substrate and the conductive film;

forming, on the interlayer dielectric film, a mask comprising a pattern which opens above a part or a whole of an upper surface of the conductive film;

exposing the upper surface of the conductive film by etching the interlayer dielectric film by using the mask; and

performing at least one of the steps of performing a treatment using one of an aqueous solution of at least one of ammonia and amine, the amine being selected from primary amine, secondary amine, tertiary amine, and quaternary amine, a treatment using a liquid chemical containing fluorine and at least one of amine, the amine being selected from primary amine, secondary amine, tertiary amine, and quaternary amine, and a treatment using a liquid chemical containing at least ammonia and fluorine and including a pH of not less than 6, particularly, not less than 9.

According to one aspect of the present invention, there is provided a semiconductor device fabrication method comprising:

forming a first interlayer dielectric film on a semiconductor substrate;

removing a desired region of the first interlayer dielectric film, and forming a film by depositing a conductive material such that the conductive material is buried in the removed region;

planarizing the film such that the film has substantially the same height as the first interlayer dielectric film, thereby burying the conductive material to form a conductive layer;

forming a second interlayer dielectric film on the first interlayer dielectric film and the buried conductive layer;

forming, on the second interlayer dielectric film, a mask comprising a pattern which opens above a part or a whole of an upper surface of the conductive layer;

exposing the upper surface of the conductive layer by etching the second interlayer dielectric film by using the mask; and

performing at least one of the steps of performing, on the exposed upper surface of the conductive layer, a treatment using one of an aqueous solution of at least one of ammonia and amine, the amine being selected from primary amine, secondary amine, tertiary amine, and quaternary amine, a treatment using a liquid chemical containing fluorine and at least one of amine, the amine being selected from primary amine, secondary amine, tertiary amine, and quaternary amine, and a treatment using a liquid chemical containing at least ammonia and fluorine and including a pH of not less than 6, particularly, not less than 9.

According to one aspect of the present invention, there is provided a semiconductor device fabrication method comprising:

forming an interlayer dielectric film on a semiconductor substrate;

removing a desired region of the interlayer dielectric film, and forming a film by depositing a conductive material such that the conductive material is buried in the removed region;

planarizing the film such that the film has substantially the same height as the interlayer dielectric film, thereby burying the conductive material to form a first conductive layer; and

performing at least one of the steps of performing, on an upper surface of the buried first conductive layer, a treatment using one of an aqueous solution of at least one of ammonia and amine, the amine being selected from primary amine, secondary amine, tertiary amine, and quaternary amine, a treatment using a liquid chemical containing fluorine and at least one of amine, the amine being selected from primary amine, secondary amine, tertiary amine, and quaternary amine, and a treatment using a liquid chemical containing at least ammonia and fluorine and including a pH of not less than 6, particularly, not less than 9.

### BRIEF DESCRIPTION OF THE DRAWINGS

FIG. 1 is a longitudinal sectional view showing the sectional structure of an element in a predetermined step of a semiconductor device fabrication method according to the first embodiment of the present invention;

FIG. 2 is a longitudinal sectional view showing the sectional structure of an element in a predetermined step of the semiconductor device fabrication method;

FIG. 3 is a longitudinal sectional view showing the sectional structure of an element in a predetermined step of the semiconductor device fabrication method;

FIG. 4 is a longitudinal sectional view showing the sectional structure of an element in a predetermined step of the semiconductor device fabrication method;

FIG. 5 is a longitudinal sectional view showing the sectional structure of an element in a predetermined step of the semiconductor device fabrication method;

FIG. 6 is a longitudinal sectional view showing the sectional structure of an element in a predetermined step of the semiconductor device fabrication method;

FIG. 7 is a longitudinal sectional view showing the sectional structure of an element in a predetermined step of the semiconductor device fabrication method;

FIG. 8 is a longitudinal sectional view showing the sectional structure of an element in a predetermined step of the semiconductor device fabrication method;

FIG. 9 is a longitudinal sectional view showing the sectional structure of an element in a predetermined step of the semiconductor device fabrication method;

FIG. 10 is a longitudinal sectional view showing the sectional structure of an element in a predetermined step of the semiconductor device fabrication method;

FIG. 11 is a graph showing the film thickness of a tungsten oxide film before and after the film is treated by using an aqueous dilute choline solution;

FIG. 12 is a view showing the relationships between interlayer dielectric films and their etching amounts;

FIG. 13 is a longitudinal sectional view showing the sectional structure of an element in a predetermined step of a semiconductor device fabrication method according to the second embodiment of the present invention;

FIG. 14 is a graph showing the relationship between the molar ratio of hydrogen fluoride to choline in a liquid chemical prepared by adding hydrogen fluoride to an aqueous dilute choline solution, and the pH of the liquid chemical;

FIG. 15 is a graph showing the relationship between the concentration of hydrogen fluoride in a liquid chemical prepared by adding hydrogen fluoride to an aqueous dilute choline solution, and the etching rate of an interlayer dielectric film;

FIG. 16 is a graph showing the relationship between the concentration of hydrogen fluoride in a liquid chemical prepared by adding hydrogen fluoride to an aqueous dilute choline solution, and the etching rate of a tungsten oxide film;

FIG. 17 is a longitudinal sectional view showing the sectional structure of an element in a predetermined step of a semiconductor device fabrication method according to the third embodiment of the present invention;

FIG. 18 is a longitudinal sectional view showing the sectional structure of an element in a predetermined step of the semiconductor device fabrication method;

FIG. 19 is a longitudinal sectional view showing the sectional structure of an element in a predetermined step of the semiconductor device fabrication method;

FIG. 20 is a longitudinal sectional view showing the sectional structure of an element in a predetermined step of the semiconductor device fabrication method;

FIG. 21 is a longitudinal sectional view showing the sectional structure of an element in a predetermined step of the semiconductor device fabrication method;

FIG. 22 is a longitudinal sectional view showing the sectional structure of an element in a predetermined step of the semiconductor device fabrication method;

FIG. 23 is a longitudinal sectional view showing the sectional structure of an element in a predetermined step of a semiconductor device fabrication method according to the fourth embodiment of the present invention;

FIG. 24 is a longitudinal sectional view showing the sectional structure of an element in a predetermined step of the semiconductor device fabrication method;

FIG. 25 is a longitudinal sectional view showing the sectional structure of an element in a predetermined step of the semiconductor device fabrication method;

FIG. 26 is a longitudinal sectional view showing the sectional structure of an element in a predetermined step of the semiconductor device fabrication method;

FIG. 27 is a longitudinal sectional view showing the sectional structure of an element in a predetermined step of the semiconductor device fabrication method;

FIG. 28 is a longitudinal sectional view showing the sectional structure of an element in a predetermined step of the semiconductor device fabrication method;

FIG. 29 is a longitudinal sectional view showing the sectional structure of an element in a predetermined step of a semiconductor device fabrication method according to the fifth embodiment of the present invention;

FIG. 30 is a longitudinal sectional view showing the sectional structure of an element in a predetermined step of the semiconductor device fabrication method;

FIG. 31 is a longitudinal sectional view showing the sectional structure of an element in a predetermined step of the semiconductor device fabrication method;

FIG. 32 is a longitudinal sectional view showing the sectional structure of an element in a predetermined step of the semiconductor device fabrication method;

FIG. 33 is a longitudinal sectional view showing the sectional structure of an element in a predetermined step of the semiconductor device fabrication method;

FIG. 34 is a longitudinal sectional view showing the sectional structure of an element in a predetermined step of the semiconductor device fabrication method;

FIG. 35 is a longitudinal sectional view showing the sectional structure of an element in a predetermined step of the semiconductor device fabrication method;

FIG. 36 is a longitudinal sectional view showing the sectional structure of an element in a predetermined step of the semiconductor device fabrication method;

FIG. 37 is a longitudinal sectional view showing the sectional structure of an element in a predetermined step of the semiconductor device fabrication method; and

FIG. 38 is a longitudinal sectional view showing the sectional structure of an element in a predetermined step of a semiconductor device fabrication method according to the sixth embodiment of the present invention.

### DETAILED DESCRIPTION OF THE INVENTION

Embodiments of the present invention will be described below with reference to the accompanying drawings.

### (1) First Embodiment

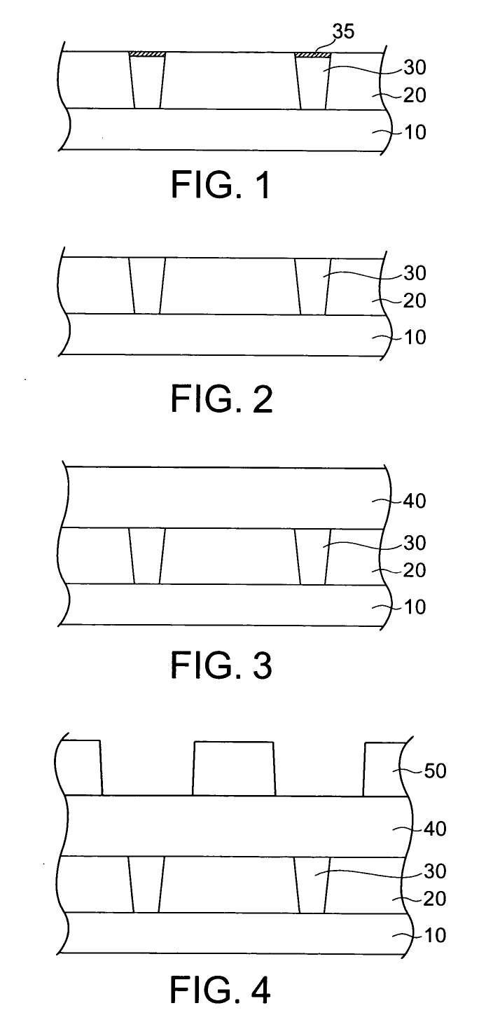

FIGS. 1 to 10 illustrate a semiconductor device fabrication method according to the first embodiment of the present invention. First, as shown in FIG. 1, an interlayer dielectric film 20 made of, e.g., a silicon oxide (SiO₂) film is formed on a semiconductor substrate 10 having a semiconductor element such as a MISFET, and the surface of the interlayer dielectric film 20 is planarized by CMP (Chemical Mechanical Polishing) or the like.

Note that in order to avoid the problem of a wiring delay, a low-k film having a dielectric constant lower than that of a silicon oxide (SiO₂) film may also be used as the interlayer dielectric film 20. As this low-k film, it is possible to use, e.g., an organic low-k film made of an organic material, an SiOF film formed by doping (adding) fluorine in a silicon oxide (SiO₂) film, an SiOC film formed by doping (adding) a few % of carbon in a silicon oxide (SiO₂) film, a porous SiOC film, or an SiCN film. Two or more types of these films may also be combined by stacking them.

Contact holes are formed by removing predetermined regions of the interlayer dielectric film 20. After that, tungsten (W) as a conductive material is deposited on the semiconductor substrate 10 and interlayer dielectric film 20 so as to be buried in the contact holes, thereby forming a tungsten film.

This tungsten film is then planarized to form tungsten plugs 30 in the interlayer dielectric film 20. The tungsten plug 30 is a plug which connects the surface of the semiconductor substrate 10 and an interconnecting layer. Note that this plug is not limited to the tungsten plug 30, and may also be a polysilicon plug or another metal plug such as a titanium plug. Alternatively, it is possible to form a plug containing at least one of tungsten and titanium. When a metal plug such as a tungsten plug is to be formed, a barrier metal is desirably stacked as an underlying layer.

As the barrier metal of tungsten, for example, it is possible to use titanium (Ti) and titanium nitride (TiN) singly or together.

Since the upper surfaces of the tungsten plugs 30 oxidize by native oxidation during or after the planarization of the tungsten film, tungsten oxide films 35 are formed on the upper surfaces of the tungsten plugs 30. It is desirable to remove the tungsten oxide films 35 because they raise the contact resistance.

As shown in FIG. 2, the tungsten oxide films 35 are etched away by treating the upper surfaces of the tungsten plugs 30 by using an aqueous dilute choline (2-hydroxyethyltrimethylammonium hydroxide) solution. This treatment using the aqueous dilute choline solution can also remove the deposit such as the slurry residue.

This makes it possible to avoid the rise of the contact resistance, thereby suppressing variations in characteristics and increasing the yield. Note that treatment conditions for effectively removing the tungsten oxide films 35 will be described later.

As shown in FIG. 3, an interlayer dielectric film 40 made of, e.g., a silicon oxide (SiO₂) film is deposited on the interlayer dielectric film 20 and tungsten plugs 30. Like the interlayer dielectric film 20, the interlayer dielectric film 40 may also be a low-k film having a dielectric constant lower than that of a silicon oxide (SiO₂) film. As this low-k film, it is possible to use an organic low-k film, SiOF film, SiOC film, porous SiOC film, SiCN film, or the like. Two or more types of these films may also be combined by stacking them.

As shown in FIG. 4, the interlayer dielectric film 40 is coated with a photoresist, and the photoresist is exposed and developed to form a resist mask 50 having a pattern which opens above the upper surfaces of the tungsten plugs 30.

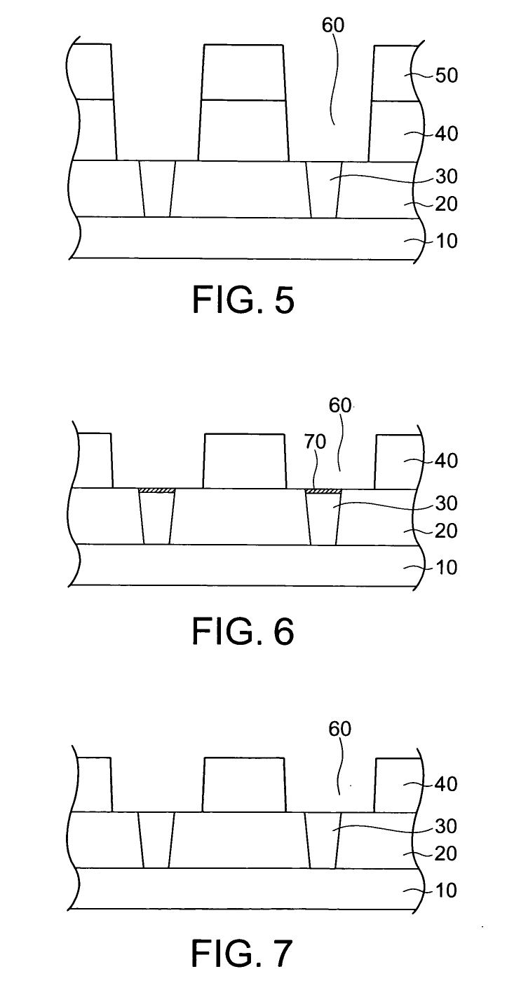

As shown in FIG. 5, the resist mask 50 is used as a mask to etch away the interlayer dielectric film 40 to a depth substantially leveled with the upper ends of the tungsten plugs 30, thereby forming interconnecting trenches 60 in the interlayer dielectric film 40, and exposing the upper surfaces of the tungsten plugs 30.

As shown in FIG. 6, ashing is performed to oxidize away the resist mask 50. During this ashing, the exposed upper surfaces of the tungsten plugs 30 are oxidized to form tungsten oxide films 70 on them. It is desirable to remove the tungsten oxide films 70 because they raise the contact resistance.

It is also possible to deposit a different film serving as a hard mask on the interlayer dielectric film 40 shown in FIG. 4, process the hard mask by the resist mask 50 to transfer the pattern of the resist mask 50 onto the hard mask, and then remove the resist mask 50 by ashing or the like. In this case, the upper surfaces of the tungsten plugs 30 can be exposed by removing the interlayer dielectric film 40 to a depth substantially leveled with the upper ends of the tungsten plugs 30 by using the hard mask as a mask. During this process, tungsten oxide films 70 are formed on the upper surfaces of the tungsten plugs 30 by native oxidation.

As shown in FIG. 7, the tungsten oxide films 70 are etched away by treating the upper surfaces of the tungsten plugs 30 by using an aqueous dilute choline solution.

Methods of removing the tungsten oxide films 70 by using the aqueous dilute choline solution are as follows. That is, in single wafer processing, the tungsten oxide films 70 are removed by discharging the aqueous dilute choline solution onto the upper surfaces of the tungsten plugs 30. In batch processing, the tungsten oxide films 70 are removed by dipping the semiconductor substrates 10 into the aqueous dilute choline solution.

As treatment conditions for effectively removing the tungsten oxide films 70, the concentration of the aqueous dilute choline solution is desirably 0.01 to 10 wt %. Especially in single wafer processing, the aqueous dilute choline solution desirably has a concentration of 0.1 to 0.5 wt %, and a temperature of 40° C. to 80° C. However, the temperature of the aqueous dilute choline solution need only be melting point to boiling point, for example at 1 atm, about 0° C. to 100° C. Usually the temperature of cooling water supplied in a facility is about 15 to 25° C. Then the temperature of choline solution is desirably more than 15° C. (inclusive).

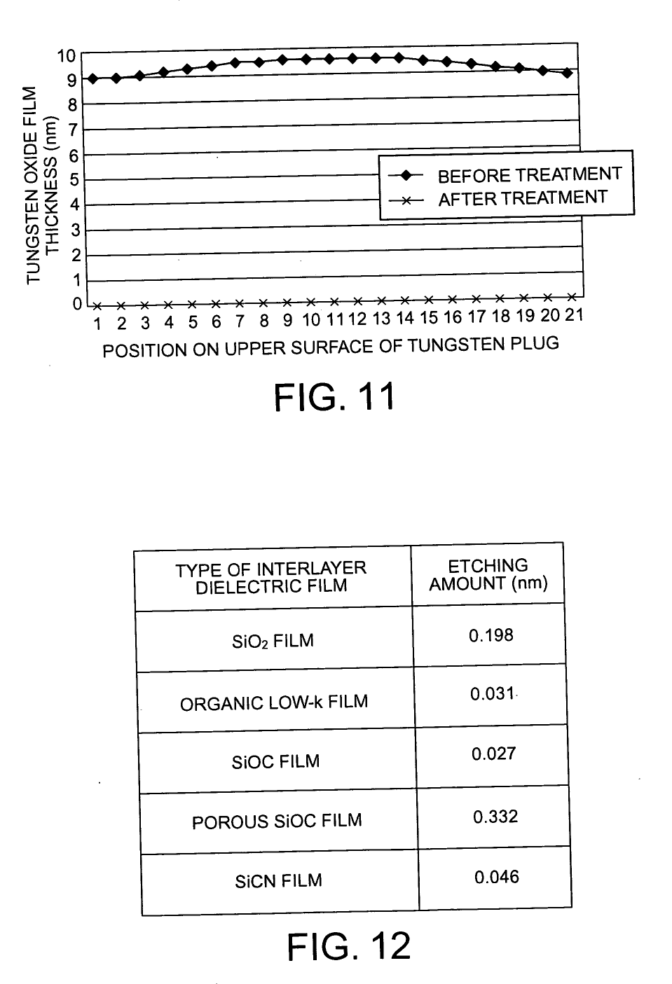

As shown in FIG. 11, the tungsten oxide films 70 can be removed by about 9 nm when treated at a temperature of 80° C. for 90 sec by using an aqueous dilute choline solution at a concentrate of 0.1 to 0.5 wt %. Referring to FIG. 11, the abscissa indicates positions in the radial direction on the surface of a circular substrate 200 mm in diameter. These positions are so set that the end point is position 1, the central point is position 11, and the other end point is position 21 on a line passing the central point of the substrate.

That is, as shown in FIG. 11, the thickness of the tungsten oxide film 70 is about 9 nm before the film is treated by using the aqueous dilute choline solution, and about 0 nm after the film is treated by using the aqueous dilute choline solution.

When the aqueous dilute choline solution is used as an etching solution, the tungsten oxide films 70 having a higher etching rate and higher selectivity than those of the silicon oxide (SiO₂) film forming the interlayer dielectric film 40 are easily etched.

Accordingly, when the treatment is performed at a temperature of 80° C. for 120 sec by using an aqueous dilute choline solution at a concentration of, e.g., 0.1 to 0.5 wt %, the etching amount of the tungsten oxide films 70 is about 9 nm, whereas the etching amount of the interlayer dielectric film 40 can be decreased to 1 nm or less, as shown in FIG. 12, regardless of the type of the interlayer dielectric film 40.

More specifically, the etching amount of the interlayer dielectric film 40 is 0.198, 0.031, 0.027, 0.332, and 0.046 nm when the interlayer dielectric film 40 is a silicon oxide (SiO₂) film, organic low-k film, SiOC film, porous SiOC film, and SiCN film, respectively.

By contrast, when a typical chemical which contains an organic solvent as a major ingredient and NH₄F is used as an etching solution, the etching amount of the interlayer dielectric film increases because its etching rate increases. When the treatment is performed for 120 sec by using the typical chemical which contains an organic solvent as a major ingredient and NH₄F, therefore, the etching amount is about 2 to 3 nm if the interlayer dielectric film is a silicon oxide (SiO₂) film.

As described above, when the aqueous dilute choline solution is used as an etching solution, it is possible to remove the tungsten oxide films 70 and decrease the etching amount of the interlayer dielectric film 40 at the same time. Therefore, the tungsten oxide films 70 can be removed without increasing the width of the interconnecting trenches 60 formed in the interlayer dielectric film 40, i.e., without increasing the width of copper interconnections to be formed later. Other steps are the same as in the above embodiment, so an explanation thereof will be omitted.

Note that when the aqueous dilute choline solution is discharged in single wafer processing, hot water may also be discharged together with the aqueous dilute choline solution. The temperature of this hot water can be selected from room temperature (inclusive) to 100° C. (exclusive).

It is also possible to remove those portions of the surfaces of the interlayer dielectric films 20 and 40, which are modified by the various processes such as the etching step and ashing step, by adding a slight amount of hydrogen fluoride (HF) or a fluorine compound (e.g., ammonium fluoride (NH₄F) or an organic fluorine compound) to the aqueous dilute choline solution.

Alternatively, a dilute HF treatment may also be performed simultaneously with the treatment using the aqueous dilute choline solution, or the individual treatments may also be performed in succession. Although details of this dilute HF treatment will be explained in the second embodiment, the HF concentration is preferably 10 wt % or less, and particularly preferably, 0.01 to 0.1 wt %, in order to suppress etching of the interlayer dielectric film. The resist residue was actually effectively removed when a treatment using HF at a concentration of about 0.05 wt % was performed for 30 sec, and then a treatment using an aqueous choline solution at a concentration of about 0.1 wt % was performed for 30 sec in succession.

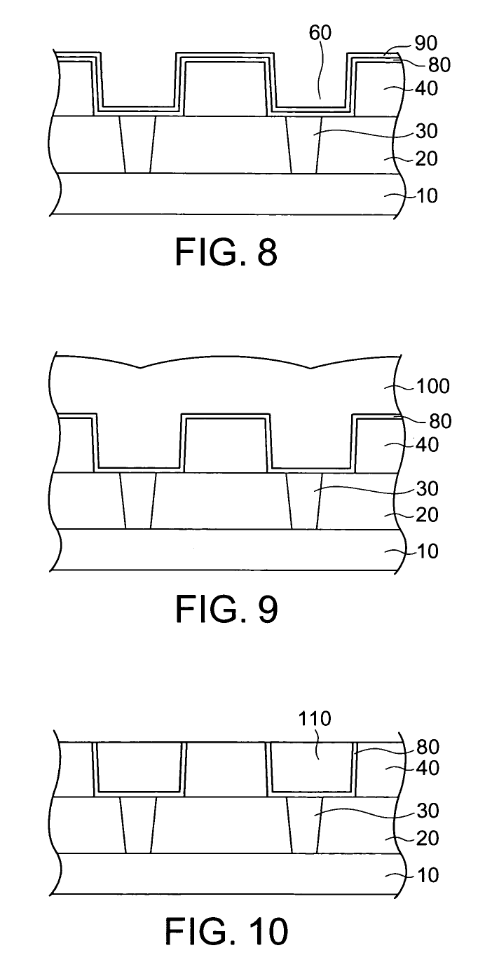

As shown in FIG. 8, a barrier metal film 80 and a seed copper (Cu) film 90 serving as a seed layer for plating are sequentially formed on the entire surfaces of the interlayer dielectric films 20 and 40 by sputtering. After that, as shown in FIG. 9, a film mainly containing copper is formed on the entire surface by plating, thereby forming the barrier metal film 80 and a copper film 100.

As this barrier metal, it is possible to use, e.g., tantalum (Ta), tantalum nitride (TaN), titanium (Ti), and titanium nitride (TiN) singly or together.

As shown in FIG. 10, copper interconnections 110 are formed by polishing the barrier metal film 80 and copper film 100 by CMR In this manner, the copper interconnections 110 having a width corresponding to the photomask can be formed, so the wiring resistance can be made equal to the design value. It is also possible to ensure a spacing between the adjacent copper interconnections 110, thereby avoiding a short circuit between them. Note that instead of the copper interconnections 110, it is also possible to form metal interconnections made of a material containing at least one of, e.g., aluminum (Al), tungsten, and copper, or made of another metal.

Interconnections may also be formed on the semiconductor substrate 10 instead of the plugs 30. Alternatively, both plugs and interconnections may also be formed on the semiconductor substrate 10.

It is also possible to form plugs, or interconnections and plugs, instead of the copper interconnections 110.

Furthermore, the material of the copper interconnections 110 or the material of plugs or plugs and interconnections formed instead of the copper interconnections is not limited to copper. That is, it is possible to use a material containing at least one of metal materials such as tungsten, titanium, tantalum, and aluminum. It is of course also possible to use another metal.

### (2) Second Embodiment

When the interlayer dielectric film 40 is etched in the first embodiment described above, residues 75 containing silicon oxide (SiOₓ), tungsten oxide (WOₓ), organic substances, and the like remain on the inner surfaces of the interconnecting trenches 60. It is desirable to remove the residues 75 because they deteriorate the transistor characteristics.

As described above, when an aqueous dilute choline solution is used as an etching solution, the tungsten oxide films 70 can be removed without increasing the width of the interconnecting trenches 60, but the residues 75 are often difficult to remove. To remove the residues 75, a liquid chemical containing, e.g., hydrogen fluoride (HF) or the like must be used.

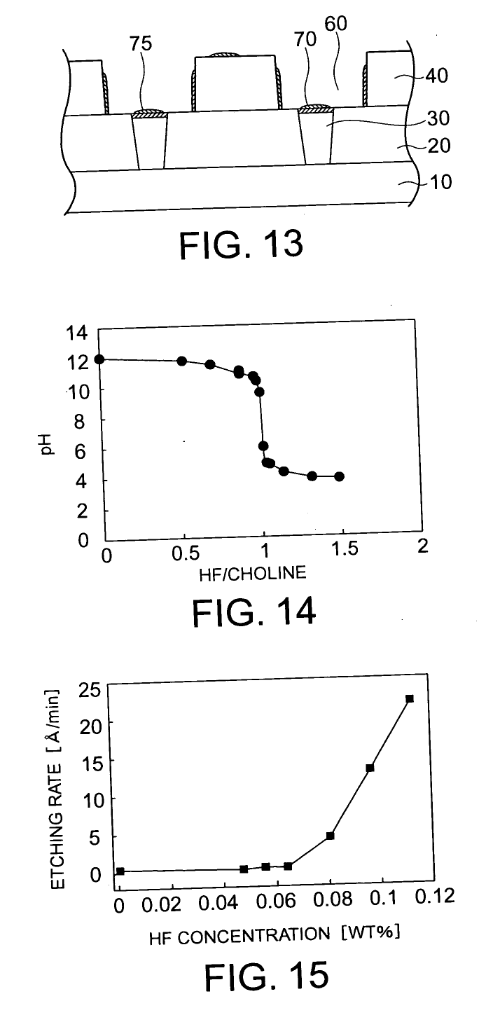

In this embodiment as shown in FIG. 13, therefore, the inner surfaces of interconnecting trenches 60 are treated by using a liquid chemical obtained by adding a slight amount of hydrogen fluoride (an acidic substance) to an aqueous dilute choline (an alkaline substance) solution. This makes it possible to remove tungsten oxide films 70 without increasing the width of the interconnecting trenches 60, and remove residues 75 remaining on the inner surfaces of the interconnecting trenches 60.

Methods of removing the tungsten oxide films 70 and residues 75 by using the liquid chemical prepared by adding hydrogen fluoride to the aqueous dilute choline solution are as follows. That is, in single wafer processing, the tungsten oxide films 70 and residues 75 are removed by discharging the liquid chemical onto the inner surfaces of the interconnecting trenches 60. In batch processing, the tungsten oxide films 70 and residues 75 are removed by dipping semiconductor substrates 10 into the liquid chemical.

FIG. 14 shows the relationship between the molar ratio of hydrogen fluoride to choline in a liquid chemical prepared by adding hydrogen fluoride to an aqueous dilute choline solution, and the pH of the liquid chemical. As shown in FIG. 14, when the molar ratio of hydrogen fluoride to choline is low, the liquid chemical becomes an alkaline chemical having a pH of about 9 to 12. When the molar ratio of hydrogen fluoride to choline is high, the liquid chemical becomes an acidic chemical having a pH of about 3 to 6. When the molar ratio of hydrogen fluoride to choline is substantially 1, the liquid chemical becomes a substantially neutral chemical having a pH of 6 to 9.

FIG. 15 shows the relationship between the concentration of hydrogen fluoride in a liquid chemical prepared by adding hydrogen fluoride to an aqueous dilute choline solution, and the etching rate of an interlayer dielectric film 40 made of a silicon oxide film. More specifically, FIG. 15 shows the etching rate of the interlayer dielectric film 40 when the concentration of choline is adjusted to 0.38 to 0.39 wt % and the concentration of hydrogen fluoride is changed from 0 to about 0.11 wt % in the liquid chemical.

As shown in FIG. 15, when the inner surfaces of the interconnecting trenches 60 are to be treated by using the liquid chemical prepared by adding hydrogen fluoride to the aqueous dilute choline solution, if the concentration of hydrogen fluoride is 0 to about 0.064 wt %, the etching rate of the interlayer dielectric film 40 is substantially 0 [Å/min]. Therefore, the interlayer dielectric film 40 is hardly etched. If the concentration of hydrogen fluoride is higher than about 0.064 wt %, the etching rate rises as the hydrogen fluoride concentration rises, and this increases the etching amount of the interlayer dielectric film 40.

Note that if the concentration of hydrogen fluoride in the liquid chemical is 0.064 wt %, the molar ratio (FIG. 14) of hydrogen fluoride to choline is 1, so the liquid chemical becomes neutral. That is, if the pH of the liquid chemical is in a neutral-to-alkaline region, the interlayer dielectric film 40 is hardly etched. If the pH of the liquid chemical is in a neutral-to-acidic region, the etching amount of the interlayer dielectric film 40 increases as the concentration of hydrogen fluoride rises. Note that the residues 75 remaining on the inner surfaces of the interconnecting trenches 60 are easily etched because the density is lower than that of the interlayer dielectric film 40.

Similarly, when the concentration of choline is adjusted to about 4 wt %, the liquid chemical is an alkaline chemical having a pH of 9 or more if the concentration of hydrogen fluoride is 0 to about 0.65 wt %, and is a neutral chemical having a pH of 6 to 9 if the concentration of hydrogen fluoride is around 0.65 wt %. If the concentration of hydrogen fluoride further increases, the liquid chemical becomes an acidic chemical having a pH of 6 or less.

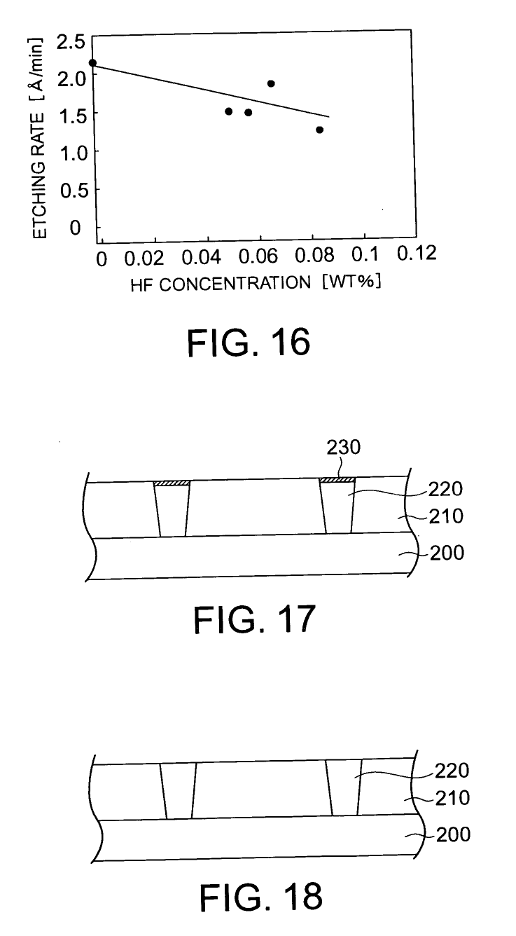

FIG. 16 shows the relationship between the concentration of hydrogen fluoride in a liquid chemical prepared by adding hydrogen fluoride to an aqueous dilute choline solution, and the etching rate of the tungsten oxide film 70. As shown in FIG. 16, as the concentration of hydrogen fluoride rises, the etching rate slightly decreases, and the etching amount of the tungsten oxide film 70 slightly reduces accordingly.

When this liquid chemical is used as an etching solution after the concentrations of choline and hydrogen fluoride in the liquid chemical are adjusted, therefore, it is possible to remove the tungsten oxide films 70 and also remove the residues 75 remaining on the inner surfaces of the interconnecting trenches 60, without increasing the width of the interconnecting trenches 60.

Note that if a small amount of silicon oxide (SiOₓ) remains as the residues 75, the tungsten oxide films 70 and residues 75 can be removed without increasing the width of the interconnecting trenches 60, by the use of a liquid chemical adjusted to a neutral-to-alkaline region where the pH is 6 or more. On the other hand, if a large amount of silicon oxide (SiOₓ) remains as the residues 75, this silicon oxide (SiOₓ) can be effectively removed by the use of a liquid chemical adjusted to a neutral-to-acidic region where the pH is 9 or less. In this case, however, it is desirable to perform the treatment for a short time period by using a liquid chemical having a pH close to a neutral region.

Treatment conditions for removing the residues 75 produced when the interlayer dielectric film 40 made of a low-k film and silicon oxide film is etched will be explained in detail below.

For example, when the treatment is performed at room temperature for 180 sec by using an alkaline liquid chemical which is so adjusted that the choline concentration is about 0.39 wt % and the hydrogen fluoride concentration is about 0.05 wt %, and has a pH of about 11 to 12, the tungsten oxide films 70 and residues 75 can be removed without increasing the width of the interconnecting trenches 60.

When the treatment is performed at room temperature for 180 sec by using a neutral liquid chemical which is so adjusted that the choline concentration is about 0.39 wt % and the hydrogen fluoride concentration is about 0.06 wt %, and has a pH which is substantially a neutralization point, the tungsten oxide films 70 and residues 75 can be removed without increasing the width of the interconnecting trenches 60.

When the treatment is performed at room temperature for 180 sec by using an acidic liquid chemical which is so adjusted that the choline concentration is about 0.38 wt % and the hydrogen fluoride concentration is about 0.09 wt %, and has a pH of about 3 to 4, the tungsten oxide films 70 and residues 75 can be removed without increasing the width of the interconnecting trenches 60.

Also, the tungsten oxide films 70 and residues 75 can be removed within a short time period if the treatment is performed by raising the concentrations of choline and hydrogen fluoride without changing the molar ratio of hydrogen fluoride to choline in the liquid chemical. Accordingly, the concentrations need only be raised if it is necessary to shorten the treatment time as in single wafer processing.

In this case, the characteristics strongly depend upon the pH rather than the concentration. If small amounts of the residues 75 remain, therefore, it is desirable to perform the treatment in a neutral-to-alkaline region where the pH is 6 or more. To remove particularly the tungsten oxide films 70, an alkaline treatment in which the pH is 9 or more is favorable. By contrast, if large amounts of the residues 75 remain, it is desirable to perform the treatment in a neutral-to-acidic region where the pH is 9 or less. Especially when a large amount of silicon oxide (SiOₓ) remains as the residues 75, an acidic treatment in which the pH is 4 or less is favorable. The pH can be freely changed by the concentration ratio in this case as well, and it is also possible to perform a plurality of treatments different in pH and/or mixing ratio in succession or together.

Furthermore, the tungsten oxide films 70 and residues 75 can be removed within a short time period if the treatment is performed by raising the temperature without changing the concentrations of choline and hydrogen fluoride. Accordingly, the temperature need only be raised if it is necessary to shorten the treatment time as in single wafer processing. When organic low-k films are used as the interlayer dielectric films 20 and 40, the temperature is desirably lower than about 40° C. In other cases, the temperature can be raised to nearly 100° C. immediately before boiling.

### (3) Third Embodiment

FIGS. 17 to 22 illustrate a semiconductor device fabrication method according to the third embodiment of the present invention. First, as shown in FIG. 17, an interlayer dielectric film 210 made of, e.g., a silicon oxide (SiO₂) film is formed on a semiconductor substrate 200, and the surface of the interlayer dielectric film 210 is planarized by CMP or the like.

Contact holes are formed by removing predetermined regions of the interlayer dielectric film 210. After that, a tungsten (W) film is deposited on the semiconductor substrate 200 and interlayer dielectric film 210 so as to be buried in the contact holes. This tungsten film is then planarized to form tungsten plugs 220 as contact plugs in the interlayer dielectric film 210.

As the barrier metal of tungsten, it is possible to use, e.g., titanium (Ti) and titanium nitride (TiN) singly or together.

Since the upper surfaces of the tungsten plugs 220 are oxidized by native oxidation during or after the planarization of the tungsten film, tungsten oxide films 230 are formed on the upper surfaces of the tungsten plugs 220. It is desirable to remove the tungsten oxide films 230 because they raise the contact resistance.

As shown in FIG. 18, in the same manner as in the first embodiment, the tungsten oxide films 230 are etched away by treating the upper surfaces of the tungsten plugs 220 by using an aqueous dilute choline solution. This makes it possible to avoid the rise of the contact resistance, thereby suppressing variations in characteristics and increasing the yield. Note that treatment conditions for effectively removing the tungsten oxide films 230 are the same as in the first embodiment.

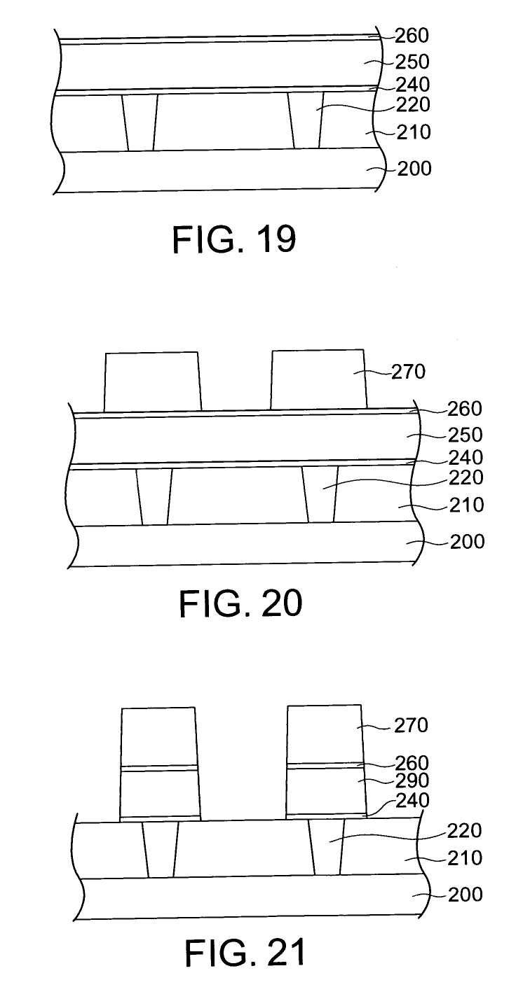

As shown in FIG. 19, a barrier metal film 240 is formed on the interlayer dielectric film 210 and tungsten plugs 220 by sputtering. After that, an aluminum (Al) film 250 as an interconnecting material is formed on the barrier metal film 240, and a barrier metal film 260 is formed on the aluminum (Al) film 250.

The barrier metal films 240 and 260 may also be formed by using, e.g., titanium (Ti) and titanium nitride (TiN) singly or together.

It should be appreciated that the interconnecting material formed on the interlayer dielectric film 210 and tungsten plugs 220 via the barrier metal film 240 is not limited to the aluminum (Al) film 250, and it is also possible to use various interconnecting materials such as tungsten. It should be also appreciated that the semiconductor device fabrication method may not comprise forming the upper barrier metal film 260 of the lower and upper barrier metal films 240 and 260.

As shown in FIG. 20, the barrier metal film 260 is coated with a photoresist, and the photoresist is exposed and developed to form a resist mask 270 having a pattern corresponding to the tungsten plugs 220.

As shown in FIG. 21, the resist mask 270 is used as a mask to etch away predetermined regions of the barrier metal film 240, aluminum (Al) film 250, and barrier metal film 260, thereby forming aluminum interconnections 290 on the tungsten plugs 220.

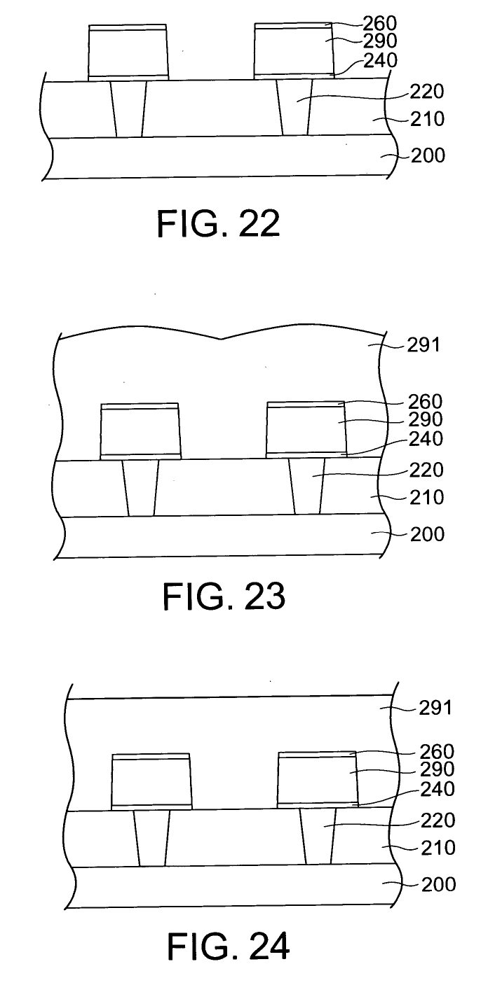

As shown in FIG. 22, ashing is performed to oxidize away the resist mask 270. Then, tungsten plugs and aluminum interconnections are sequentially formed on the aluminum interconnections 290 to stack aluminum interconnections, thereby forming multilayered interconnections.

As described above, this embodiment makes it possible to avoid the rise of the contact resistance, thereby suppressing variations in characteristics and increasing the yield.

Although the interconnections 290 are formed on the upper surfaces of the plugs 220, plugs may also be formed instead of the interconnections on the upper surfaces of the plugs 220.

### (4) Fourth Embodiment

A semiconductor device fabrication method according to the fourth embodiment of the present invention will be explained below with reference to FIGS. 23 to 28.

In the third embodiment described above, ashing is performed to oxidize away the resist mask 270 as shown in FIG. 22. The fourth embodiment of the present invention relates to steps after that. Other steps are the same as in the third embodiment, so an explanation thereof will be omitted.

In this embodiment, a different film serving as a hard mask is deposited on a barrier metal film 260 and processed by a resist mask 270 to transfer the pattern of the resist mask 270 onto the hard mask, and then the resist mask 270 is removed by ashing or the like. In this case, it is possible to etch away predetermined regions of a barrier metal film 240, an aluminum (Al) film 250, and the barrier metal film 260 by using the hard mask as a mask, thereby forming aluminum interconnections 290 on tungsten plugs 220.

After the aluminum interconnections 290 are thus formed by using the resist mask 270 and hard mask, a treatment is performed using a liquid chemical obtained by adding a slight amount of hydrogen fluoride to an aqueous dilute choline solution in the same manner as in the first embodiment. Consequently, the residues such as the aluminum residue and resist residue can be removed, while etching of the aluminum interconnections 290 is suppressed.

This aluminum residue having a lower density than that of the aluminum interconnections 290 is easily etched. Since aluminum forms a complex with fluorine and dissolves, the aluminum residue is removed regardless of whether the pH of the liquid chemical is in a neutral-to-acidic region where the pH is 9 or less, or in a neutral-to-alkaline region where the pH is 6 or more. Therefore, a liquid chemical having an arbitrary pH and/or an arbitrary mixing ratio can be used. Note that it is also possible to combine a plurality of liquid chemicals different in pH and/or mixing ratio.

Tungsten plugs and aluminum interconnections are sequentially formed on the aluminum interconnections 290 to stack aluminum interconnections, thereby forming multilayered interconnections.

As shown in FIG. 23, an interlayer dielectric film 291 made of, e.g., a silicon oxide (SiO₂) film is deposited on the interlayer dielectric film 210 and barrier metal film 260. After that, as shown in FIG. 24, the surface of the interlayer dielectric film 291 is planarized by CMP or the like.

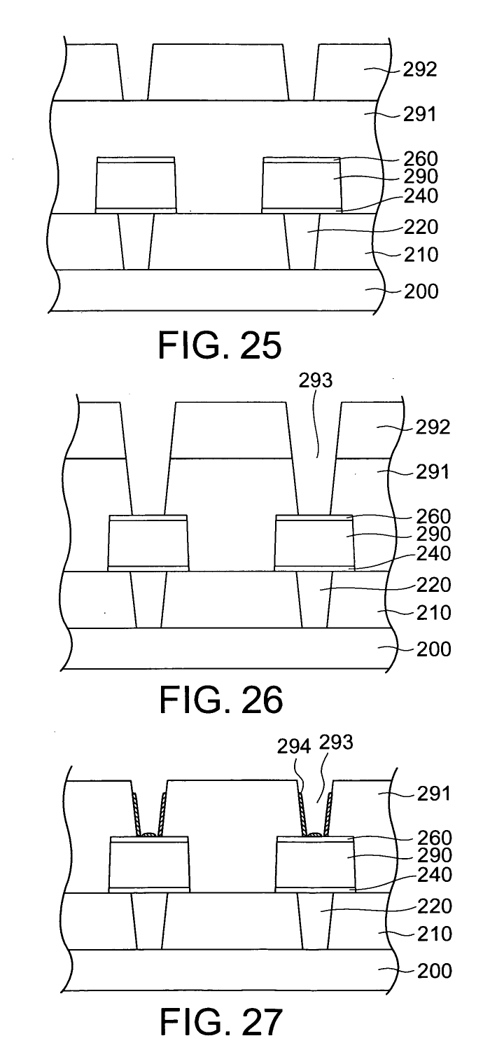

As shown in FIG. 25, the interlayer dielectric film 291 is coated with a photoresist, and the photoresist is exposed and developed to form a resist mask 292 having a pattern which opens above the upper surfaces of the barrier metal films 260.

As shown in FIG. 26, the resist mask 292 is used as a mask to etch away the interlayer dielectric film 291 to a depth substantially leveled with the upper ends of the barrier metal films 260, thereby forming contact holes 293 in the interlayer dielectric film 291, and exposing the upper surfaces of the barrier metal films 260.

As shown in FIG. 27, ashing is performed to oxidize away the resist mask 292. As in the first embodiment, residues 294 made of, e.g., silicon oxide (SiO₂) and organic substances remain on the inner surfaces of the contact holes 293 when the interlayer dielectric film 291 is etched. It is desirable to remove the residues 294 because they deteriorate the transistor characteristics.

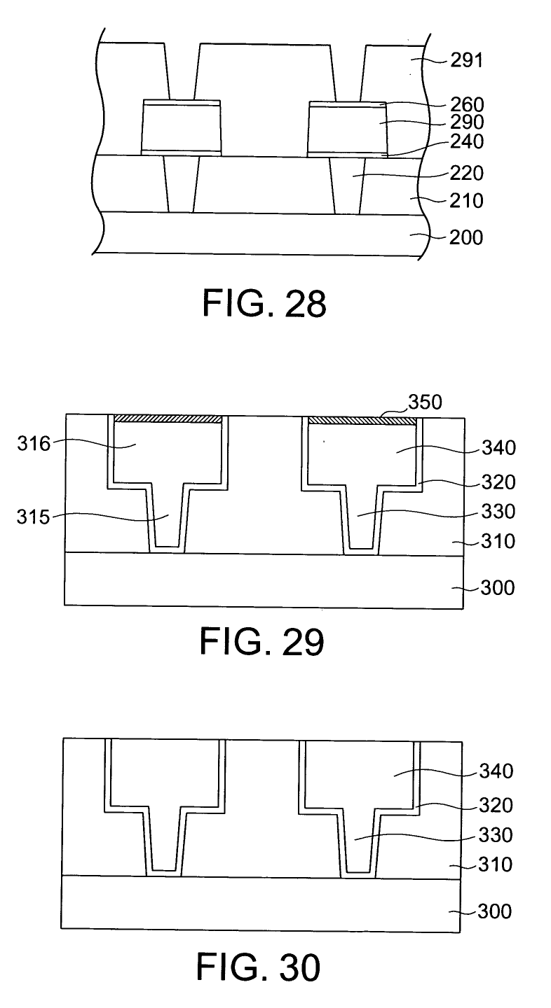

As shown in FIG. 28, in the same manner as in the second embodiment, the inner surfaces of the contact holes 293 are treated by using a liquid chemical obtained by adding a slight amount of hydrogen fluoride to an aqueous dilute choline solution. This makes it possible to remove the residues 294 remaining on the inner surfaces of the contact holes 293 without increasing the width of the contact holes 293. Note that treatment conditions for effectively removing the residues 294 are the same as in the first embodiment. That is, it is possible to use a liquid chemical having an arbitrary pH and/or an arbitrary mixing ratio, and combine a plurality of liquid chemicals different in pH and/or mixing ratio.

### (5) Fifth Embodiment

FIGS. 29 to 37 illustrate a semiconductor device fabrication method according to the fifth embodiment of the present invention. First, as shown in FIG. 29, an interlayer dielectric film 310 made of, e.g., a silicon oxide (SiO₂) film is formed on a semiconductor substrate 300, and the surface of the interlayer dielectric film 310 is planarized by CMP or the like.

A resist mask for forming contact holes is formed on the interlayer dielectric film 310, and used as a mask to etch away plug formation regions of the interlayer dielectric film 310, thereby forming contact holes 315. After that, the resist mask for forming contact holes is removed.

In addition, a resist mask for forming interconnecting trenches is formed. After the etching time is designated, this resist mask is used as a mask to etch away interconnection formation regions of the interlayer dielectric film 310, thereby removing the interlayer dielectric film 310 to a predetermined depth to form interconnecting trenches 316. Then, the resist mask for forming interconnecting trenches is removed.

A barrier metal film 320 is formed on the inner surfaces of the contact holes 315 and interconnecting trenches 316, and a tungsten (W) film is so deposited as to bury the barrier metal film 320 and the tungsten film. The barrier metal film 320 and tungsten film are then planarized to form tungsten plugs 330 as contact plugs and tungsten interconnections 340 in the interlayer dielectric film 310.

The barrier metal film 320 may also be formed by using, e.g., titanium (Ti) and titanium nitride (TiN) singly or together.

Since the upper surfaces of the tungsten interconnections 340 are oxidized by native oxidation during or after the planarization of the tungsten film, tungsten oxide films 350 are formed on the upper surfaces of the tungsten interconnections 340. It is desirable to remove the tungsten oxide films 350 because they raise the contact resistance.

As shown in FIG. 30, the tungsten oxide films 350 are etched away by treating the upper surfaces of the tungsten interconnections 340 with an aqueous dilute choline solution. This makes it possible to avoid the rise of the contact resistance, thereby suppressing variations in characteristics and increasing the yield. Note that treatment conditions for effectively removing the tungsten oxide films 350 are the same as in the first embodiment.

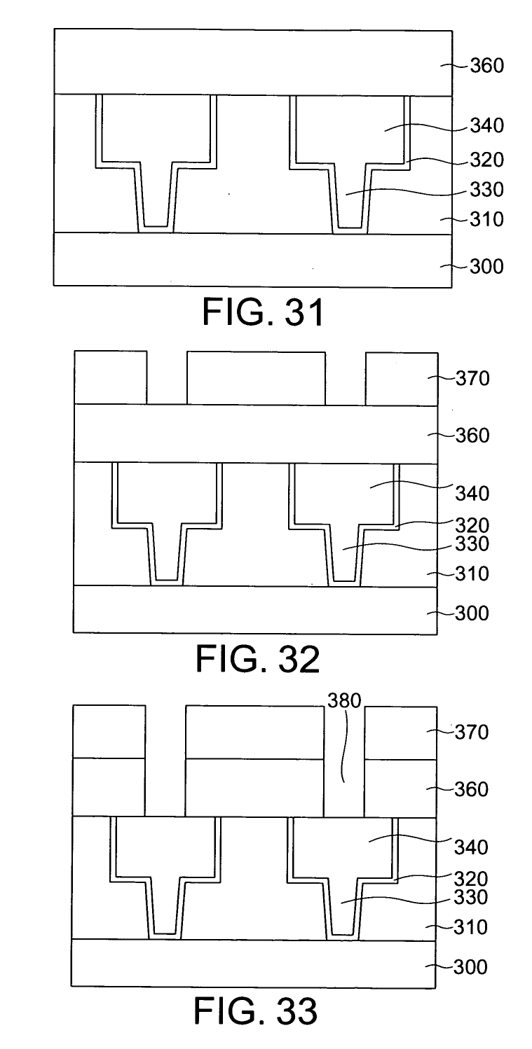

As shown in FIG. 31, an interlayer dielectric film 360 made of, e.g., a silicon oxide (SiO₂) film is deposited on the interlayer dielectric film 310, barrier metal film 320, and tungsten interconnections 340. As shown in FIG. 32, the interlayer dielectric film 360 is coated with a photoresist, and the photoresist is exposed and developed to form a resist mask 370 having a pattern which opens above the upper surfaces of the tungsten interconnections 340.

The interlayer dielectric film may also be formed by using a low-k film such as an organic low-k film, SiOF film, SiOC film, porous SiOC film, or SiCN film.

As shown in FIG. 33, the resist mask 370 is used as a mask to etch away the interlayer dielectric film 360 to a depth substantially leveled with the upper ends of the tungsten interconnections 340, thereby forming contact holes 380 in the interlayer dielectric film 360 and partially or whole exposing the upper surfaces of the tungsten interconnections 340.

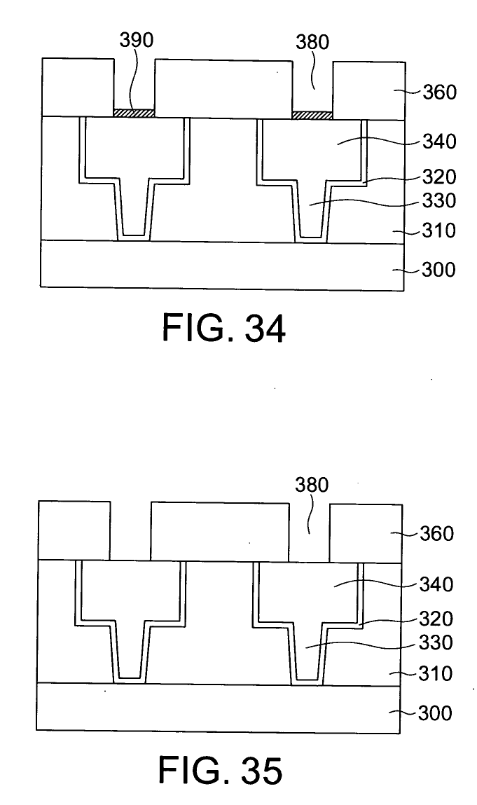

As shown in FIG. 34, ashing is performed to oxidize away the resist mask 370. During this ashing, the exposed upper surfaces of the tungsten interconnections 340 are oxidized to form tungsten oxide films 390 on portions of the upper surfaces of the tungsten interconnections 340. It is desirable to remove the tungsten oxide films 390 because they raise the contact resistance.

As shown in FIG. 35, the tungsten oxide films 390 are etched away by treating the upper surfaces of the tungsten interconnections 340 by using an aqueous dilute choline solution. Note that treatment conditions for effectively removing the tungsten oxide films 390 are the same as in the first embodiment.

When the aqueous dilute choline solution is used as an etching solution as described above, it is possible to remove the tungsten oxide films 390 and, as in the first embodiment, reduce the etching amount of the interlayer dielectric film 360. Accordingly, the tungsten oxide films 390 can be removed without increasing the width of the contact holes 380 formed in the interlayer dielectric film 360, i.e., without increasing the width of tungsten plugs to be formed later.

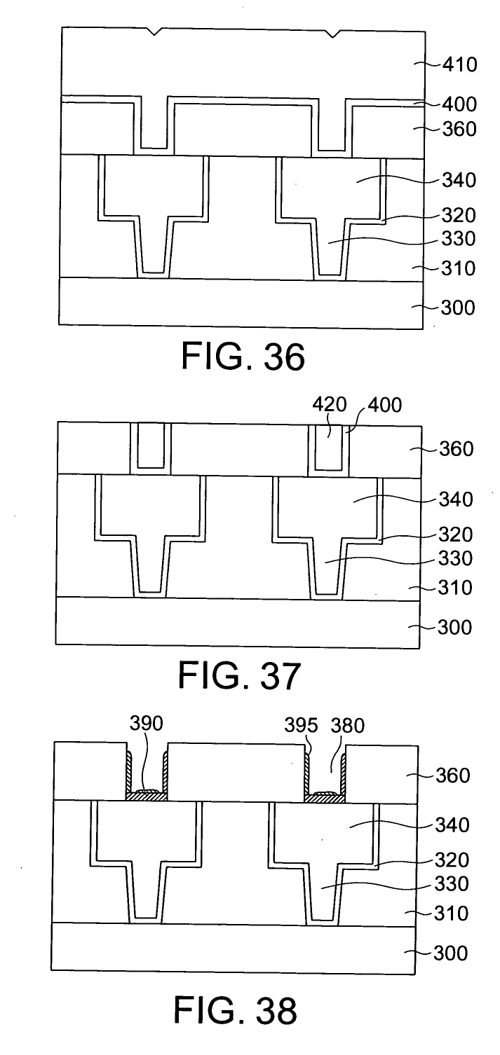

As shown in FIG. 36, a barrier metal film 400 is formed on the interlayer dielectric film 360 and tungsten interconnections 340 by sputtering and/or CVD, and a tungsten film 410 is formed on the entire surface by CVD.

As shown in FIG. 37, tungsten plugs 420 are formed by polishing the barrier metal film 400 and tungsten film 410 by CMP. Since the tungsten plugs 420 having a width corresponding to the photomask can be formed, variations in characteristics can be suppressed.

### (6) Sixth Embodiment

The sixth embodiment of the present invention will be explained below with reference to FIG. 38.

In the step shown in FIG. 33 of the fifth embodiment, it is also possible to deposit a different film serving as a hard mask on an interlayer dielectric film 360, process the hard mask by a resist mask 370 to transfer the pattern of the resist mask 370 onto the hard mask, and then remove the resist mask 370 by ashing or the like. Other steps are the same as in the fifth embodiment, so an explanation thereof will be omitted.

In this case, the hard mask is used as a mask to etch away the interlayer dielectric film 360 to a depth substantially leveled with the upper ends of tungsten interconnections 340, thereby forming contact holes 380 in the interlayer dielectric film 360, and partially exposing the upper surfaces of the tungsten interconnections 340.

During this etching, tungsten oxide films 390 form on the upper surfaces of the tungsten interconnections 340 by native oxidation. It is desirable to remove the tungsten oxide films 390 because they raise the contact resistance.

As in the second embodiment described previously, when the interlayer dielectric film 360 is etched, residues 395 made of, e.g., silicon oxide (SiO₂), tungsten oxide (WOₓ), and organic substances remain on the inner surfaces of the contact holes 380. It is desirable to remove the residues 395 because they deteriorate the transistor characteristics.

As shown in FIG. 35, in the same manner as in the first embodiment, the inner surfaces of the contact holes 380 are treated by using a liquid chemical obtained by adding a slight amount of hydrogen fluoride to an aqueous dilute choline solution. This makes it possible to remove the tungsten oxide films 390 and also remove the residues 395 remaining on the inner surfaces of the contact holes 380, without increasing the width of the contact holes 380. Note that treatment conditions for effectively removing the residues 395 are the same as in the first embodiment. That is, it is possible to use a liquid chemical having an arbitrary pH and/or an arbitrary mixing ratio, and combine a plurality of liquid chemicals different in pH and/or mixing ratio.

Each of the above embodiments is merely an example and does not limit the present invention.

For example, when the tungsten plugs 30 or 220 or the tungsten interconnections 340 are treated by using an aqueous dilute choline solution at a concentration of 0.1 to 0.5 wt %, the temperature is preferably 20° C. (inclusive) to 100° C. (exclusive), and can be freely selected as needed.

It is also possible to add a slight amount of HF, a fluorine compound, a surfactant for improving the wettability, an organic solvent for improving the resist removability, and the like to the aqueous dilute choline solution.

Furthermore, primary to quaternary amines can be used singly or together instead of choline. Examples are ammonia (NH₄OH), tetramethyl ammonium hydroxide (TM-AH), tetraethyl ammonium hydroxide, and trimethyl monomethyl ammonium hydroxide. Note that “amine” is a substance obtained by substituting one or more Hs in ammonium with hydrocarbon groups or the like. For example, primary, secondary, tertiary, and quaternary amines are substances obtained by substituting one, two, three, and four Hs, respectively.

The interconnections are not limited to tungsten, and it is also possible to use arbitrary materials such as copper, aluminum, titanium, iridium, rhodium, and ruthenium. When copper is used, for example, it is desirable to perform a treatment by using a liquid chemical in a neutral-to-acidic region where the pH is 9 or less, in order to remove copper oxide (CuOₓ).

The bottom surface of the contact hole 380 need not be an interconnection but may also be a substrate or gate electrode. In this case, a material containing an arbitrary material such as silicon, germanium, cobalt, titanium, tungsten, nickel, platinum, palladium, iridium, yttrium, erbium, or ruthenium may exist below the contact hole 380.

The inner surfaces of the interconnecting trenches 60 and contact holes 293 and 380 may also be treated by singly using a liquid chemical prepared by mixing an acidic substance, neutral substance, and alkaline substance at desired concentrations, or by successively using liquid chemicals having different molar ratios in a desired order. In this case, if an acidic liquid chemical and alkaline liquid chemical are used in succession, both the effects on the acidic side and alkaline side can be obtained. The treatment may also be performed by raising the temperature of the liquid chemical.

As the alkaline substance, primary to quaternary amines can be used singly or together instead of choline. Examples are ammonia (NH₄OH), tetramethyl ammonium hydroxide (TM-AH), tetraethyl ammonium hydroxide, and trimethyl monomethyl ammonium hydroxide.

If, however, ammonia (NH₄OH) is used in an acidic region where the pH is smaller than 6, ammonium fluoride (NH₄F) salt also exists, and this decreases the effect of NH₄⁺. Therefore, ammonia is used in a neutral-to-alkaline region where the pH is 6 or more, particularly, 9 or more.

As the acidic substance, it is possible to use, e.g., ammonium fluoride (NH₄F), acidic ammonium fluoride (NH₄FHF), and a fluorine compound salt of an organic alkaline substance singly or together instead of hydrogen fluoride.

In addition to the alkaline substance and fluorine, the liquid chemical used can further contain a salt or an acidic substance such as hydrochloric acid, sulfuric acid, phosphoric acid, nitric acid, or acetic acid, or an oxidizer such as hydrogenperoxide, or ozone.

Also, any material can be used as a conducive film for forming contact plugs, metal interconnections, a substrate, and gate electrodes. However, it is particularly favorable to form these components such that they contain at least one of tungsten, titanium, silicon, aluminum, tantalum, copper, ruthenium, cobalt, nickel, platinum, palladium, germanium, iridium, erbium, rhodium, and yttrium.

Note that a film to be etched need not be an insulating film or conductive film, and may also be a semiconductor film or semiconductor substrate.

The semiconductor device fabrication methods of the above embodiments can increase the yield by suppressing variations in characteristics.

What is claimed is:

1. A semiconductor device fabrication method comprising:
forming a film on a semiconductor substrate;
forming a mask comprising a predetermined pattern on the film;
etching one of the film and the semiconductor substrate by using the mask; and
performing at least one of the steps of performing a treatment using one of an aqueous solution of at least one of ammonia and amine, the amine being selected from primary amine, secondary amine, tertiary amine, and quaternary amine, a treatment using a liquid chemical containing fluorine and at least one of amine, the amine being selected from primary amine, secondary amine, tertiary amine, and quaternary amine, and a treatment using a liquid chemical containing at least ammonia and fluorine and including a pH of not less than 6, particularly, not less than 9.

2. A method according to claim 1, wherein the film comprises a conductive film made of a conductive material.

3. A method according to claim 2, wherein the conductive film contains at least one of tungsten, titanium, silicon, aluminum, tantalum, copper, ruthenium, cobalt, nickel, platinum, palladium, germanium, erbium, iridium, rhodium and yttrium.

4. A method according to claim 1, wherein the amine, being selected from the primary amine, secondary amine, tertiary amine, and quaternary amine contain at least one of choline, tetramethyl ammonium hydroxide, tetraethyl ammonium hydroxide, and trimethyl monomethyl ammonium hydroxide.

5. A method according to claim 1, comprising, in succession:
performing at least one of performing a treatment using one of an aqueous solution of at least one of ammonia and amine, the amine being selected from primary amine, secondary amine, tertiary amine, and quaternary amine, a treatment using a liquid chemical containing fluorine and at least one of amine, the amine being selected from primary amine, secondary amine, tertiary amine, and quaternary amine, and a treatment using a liquid chemical containing at least ammonia and fluorine and including a pH of not less than 6, particularly, not less than 9; and
performing a treatment using dilute HF.

6. A semiconductor device fabrication method comprising:
forming a conductive film by depositing a conductive material on a semiconductor substrate;
removing a desired region of the conductive film;
forming an interlayer dielectric film on the semiconductor substrate and the conductive film;
forming, on the interlayer dielectric film, a mask comprising a pattern which opens above a part or a whole of an upper surface of the conductive film;
exposing the upper surface of the conductive film by etching the interlayer dielectric film by using the mask; and
performing at least one of the steps of performing a treatment using one of an aqueous solution of at least one of ammonia and amine, the amine being selected from primary amine, secondary amine, tertiary amine, and quaternary amine, a treatment using a liquid chemical containing fluorine and at least one of amine, the amine being selected from primary amine, secondary amine, tertiary amine, and quaternary amine, and a treatment using a liquid chemical containing at least ammonia and fluorine and including a pH of not less than 6, particularly, not less than 9.

7. A semiconductor device fabrication method comprising:
forming a first interlayer dielectric film on a semiconductor substrate;
removing a desired region of the first interlayer dielectric film, and forming a film by depositing a conductive material such that the conductive material is buried in the removed region;
planarizing the film such that the film has substantially the same height as the first interlayer dielectric film, thereby burying the conductive material to form a conductive layer;
forming a second interlayer dielectric film on the first interlayer dielectric film and the buried conductive layer;
forming, on the second interlayer dielectric film, a mask comprising a pattern which opens above a part or a whole of an upper surface of the conductive layer;
exposing the upper surface of the conductive layer by etching the second interlayer dielectric film by using the mask; and
performing at least one of the steps of performing, on the exposed upper surface of the conductive layer, a treatment using one of an aqueous solution of at least one of ammonia and amine, the amine being selected from primary amine, secondary amine, tertiary amine, and quaternary amine, a treatment using a liquid chemical containing fluorine and at least one of amine, the amine being selected from primary amine, secondary amine, tertiary amine, and quaternary amine, and a treatment using a liquid chemical containing at least ammonia and fluorine and including a pH of not less than 6, particularly, not less than 9.

8. A method according to claim 7, wherein the conductive film contains at least one of tungsten, titanium, silicon, aluminum, tantalum, copper, ruthenium, cobalt, nickel, platinum, palladium, germanium, erbium, iridium, rhodium, and yttrium.

9. A method according to claim 7, wherein the amine, being selected from the primary amine, secondary amine, tertiary amine, and quaternary amine contain at least one of choline, tetramethyl ammonium hydroxide, tetraethyl ammonium hydroxide, and trimethyl monomethyl ammonium hydroxide.

10. A method according to claim 7, wherein the amine, being selected from the primary amine, secondary amine, tertiary amine, and quaternary amine comprise choline, and a concentration of choline is 0.01 to 10 wt %.

11. A method according to claim 7, wherein the amine, being selected from the primary amine, secondary amine, tertiary amine, and quaternary amine comprise choline, and a temperature of the liquid chemical is not less than 15° C.

12. A method according to claim 7, further comprising:
depositing a second conductive layer such that the second conductive layer is buried in the removed region of the second interlayer dielectric film; and
planarizing the second conductive layer such that the second conductive layer has substantially the same height as the second interlayer dielectric film.

13. A method according to claim 12, wherein the second conductive film contains at least one of tungsten, titanium, silicon, aluminum, tantalum, copper, ruthenium, cobalt, nickel, platinum, palladium, germanium, erbium, iridium, rhodium, and yttrium.

14. A semiconductor device fabrication method comprising:
forming an interlayer dielectric film on a semiconductor substrate;
removing a desired region of the interlayer dielectric film, and forming a film by depositing a conductive material such that the conductive material is buried in the removed region;
planarizing the film such that the film has substantially the same height as the interlayer dielectric film, thereby burying the conductive material to form a first conductive layer; and
performing at least one of the steps of performing, on an upper surface of the buried first conductive layer, a treatment using one of an aqueous solution of at least one of ammonia and amine, the amine being selected from primary amine, secondary amine, tertiary amine, and quaternary amine, a treatment using a liquid chemical containing fluorine and at least one of amine, the amine being selected from primary amine, secondary amine, tertiary amine, and quaternary amine, and a treatment using a liquid chemical containing at least ammonia and fluorine and including a pH of not less than 6, particularly, not less than 9.

15. A method according of claim 14, wherein the region of the interlayer dielectric film which is to be removed is at least one of a plug formation region for forming a plug, and an interconnection formation region for forming an interconnection.

16. A method according to claim 14, wherein the conductive film contains at least one of tungsten, titanium, silicon, aluminum, tantalum, copper, ruthenium, cobalt, nickel, platinum, palladium, germanium, erbium, iridium, rhodium, and yttrium.

17. A method according to claim 14, wherein the amine, being selected from the primary amine, secondary amine, tertiary amine, and quaternary amine contain at least one of choline, tetramethyl ammonium hydroxide, tetraethyl ammonium hydroxide, and trimethyl monomethyl ammonium hydroxide.

18. A method according to claim 14, wherein the amine, being selected from the primary amine, secondary amine, tertiary amine, and quaternary amine comprise choline, and a concentration of choline is 0.01 to 10 wt %.

19. A method according to claim 14, wherein the amine, being selected from the primary amine, secondary amine, tertiary amine, and quaternary amine comprise choline, and a temperature of the liquid chemical is not less than 15° C.

20. A method according to claim 14, further comprising:
forming a film by depositing a conductive material on the interlayer dielectric film and the first conductive layer;
forming, on the film, a mask comprising a pattern corresponding to the first conductive layer; and
forming a second conductive layer by etching the film by using the mask.
